(19) United States
(12) Patent Application Publication
(10) Pub. No.: US 2011/0147051 A1
(43) Pub. Date: Jun. 23, 2011

(54) CAPACITIVE SWITCH SENSORS ON DECORATIVE IN-MOLD FILMS BACKGROUND

(75) Inventors: Michael J. Sims, Zeeland, MI (US); Michael R. Catlin, Holland, MI (US)

(73) Assignee: JOHNSON CONTROLS TECHNOLOGY COMPANY, Holland, MI (US)

(21) Appl. No.: 12/996,632

(22) PCT Filed: Jun. 10, 2009
(86) PCT No.: PCT/IB09/06394

§ 371 Date: Jan. 3, 2011

Related U.S. Application Data
(60) Provisional application No. 61/060,287, filed on Jun. 10, 2008.

(51) Int. Cl. H05K 1/00; H05K 1/09; B41F 33/00

(52) U.S. Cl. 174/254; 174/257; 101/483

(57) ABSTRACT

This invention is related to process for the production of a interior trim piece, comprising the steps of: —providing a film layer—applying conductive ink/paint to the back surface of the film layer to provide a circuit path and—attaching a substrate on the back surface of the film layer. This invention further relates to a interior trim piece comprising a film layer with a circuit path on its back surface, whereas the circuit path is made from conductive ink/paint.

### BACKGROUND

1. Field of the Invention

This invention is related to process for the production of a interior trim piece, comprising the steps of:
providing a film layer
applying conductive ink/paint to the back surface of the film layer to provide a circuit path and
attaching a substrate on the back surface of the film layer.

This invention further relates to a interior trim piece comprising a film layer with a circuit path on its back surface, whereas the circuit path is made from conductive ink/paint.

2. Background of the Invention

Interior trim pieces provide aesthetic finishes to the interior of vehicles. It is known to provide interior trim pieces that are made by injection molding a substrate to the back surface of a film layer. It is also known to provide interior trim pieces that include electrical circuits, buttons or switches to control various electrical and/or mechanical systems of the vehicle. For example, an overhead console of a vehicle may include electrical circuits, buttons to control various window motors or interior lights of the vehicle. Additionally, it is known to provide buttons or switches that utilize a determined capacitance or a change in capacitance as the switching condition.

Current designs of capacitive switches in interior trim pieces of a vehicle require a conductive coating that is provided on a secondary piece. The secondary piece with the conductive coating is then attached to the trim piece. This secondary piece with the conductive coating may be a printed circuit board, a flex circuit or a conductive indium tin oxide (ITO) layer on glass, and may contain one or more conductive paths or circuits.

### SUMMARY

Although capacitive switches may be preferable over traditional mechanical switches due to their potential for a reduced part count and simplified design, current capacitive switch designs have significant design flaws that negatively impact their operation. Current designs of capacitive switches, with a secondary piece attached to an interior trim piece of a vehicle, create a substantially large gap between the conductive coating and the show surface of the vehicle. This gap negatively impacts the operation of the capacitive switch by limiting sensitivity and reliability. Additionally, using a secondary piece attached to an interior trim piece increases the part count of the vehicle as well as the complexity of the trim piece and the opportunity for malfunctions or manufacturing errors to occur.

It was therefore the objective of the present invention, to provide a process for the production of a interior trim piece and the trim pieces itself which overcomes the deficiencies of the state of the art.

This problem is solved with a process for the production of a interior trim piece, comprising the steps of:
providing a film layer
applying conductive ink/paint to the back surface of the film layer to provide an electrical circuit path and
attaching a substrate on the back surface of the film layer.

The present invention relates to the production of a trim piece. This trim piece can be located anywhere in the interior of a vehicle. The trim piece can be for example pstr of an overhead console, part of the dash-board of part of the door panel.

This trim piece includes a film layer made from a plastic material, which is preferably flexible. This film layer comprises a show surface which is oriented towards the interior of the vehicle. On the opposite side, the back surface the film layer, an electrical circuit path is provided. This electrical circuit path is connected to the film layer by material engagement; i.e. the electrical circuit path is in direct contact with the film layer. There is no glue or the like between the electrical circuit path and the film layer. The electrical circuit path can comprise electrical components, such as, for example, sensors, switches or the like.

Furthermore, the trim piece comprises a substrate, which is attached to the back surface of the film layer. This substrate is attached to the film layer, after the electrical circuit has been applied. The substrate preferably protects the electrical circuit on the film layer, maintains the film layer in a certain shape and/or gives the film layer material strength.

According to the present invention, the electrical circuit path is made from a conductive ink and/or paint. The conductive ink/and/or paint comprises a electrically conducting component, for example carbon silver, preferably a binder and/or a solvent, which can be an organic solvent and/or a water based solvent. Preferably, the specific electrical resistance of the electrical circuit path is <10⁻¹ ohms/cm. The thickness of the electrical coating is preferably <50 μm, more preferably <30 μm. Preferably, the conductive ink/paint is thermally so stable that a substrate can be molded to the back surface of the film layer.

Preferably, the conductive ink/paint is printed, sprayed, molded and/or screen-printed on the film layer. After the conductive ink/paint has dried, there is a material engagement between the conductive ink/paint and the back surface of the film layer. Electrical components, like capacitive switches can also be applied to the back side of the film layer by one of these methods.

The substrate can be attached to the back surface of the film layer by any method known to a person skilled in the art. However, preferably, the substrate is molded behind the film layer on its back side. Thereto, the film layer, provided with the electrical circuit, is preferably placed in a mould-cavity and the liquid substrate material is filled, for example injected, into the mould cavity on the back surface of the film layer.

Preferably, prior to applying the substrate, the film layer is preformed to a desired shape, preferably after the conductive ink/paint has been applied.

In a preferred embodiment of the present invention, the substrate covers only partially the back surface of the film layer. Especially, a projection of the film layer, is left uncovered. This projection can be used to connect the trim piece to the car electronics.

Another subject matter of the present invention is an interior trim piece comprising a film layer with an electrical circuit path on its back surface, whereas the electrical circuit path is made from conductive ink/paint.

The disclosure made regarding the inventive process also applies to the inventive trim piece and vice versa.

This invention especially relates to an interior trim piece of a vehicle that has capacitive switches incorporated into or onto the trim piece. In various exemplary embodiments, the trim piece has a film layer and preferably a substrate, which is more preferably injection molded behind at least a portion of the film layer. At least one conductive path is applied, preferably printed, onto a rear surface of the film layer more preferably before forming the substrate. The at least one conductive path is applied onto the back surface of the film layer prior to the substrate being applied, for example injection molded, behind the film layer.

This invention further relates to an interior trim piece that has a film layer show surface with a conductive path provided on the back surface of the film layer. A substrate is applied, preferably molded onto at least a first portion of the back surface of the film layer, while the substrate is not applied onto at least a second portion of the film layer containing part of the conductive path.

According to the present invention, the electrical circuit path of the trim piece is made from a conductive ink and/or paint. The conductive ink/and/or paint comprises a electrically conducting component, for example carbon, preferably a binder and/or a solvent, which can be an organic solvent and/or a water based solvent. Preferably, the specific electrical resistance of the electrical circuit path is <10⁻¹ ohms/cm. The thickness of the electrical coating is preferably <50 μm, more preferably <30 μm.

Preferably, the conductive ink/paint is thermally so stable, that a substrate can be molded to the back surface of the film layer.

Preferably, the film layer is made from a flexible plastic material.

In a preferred embodiment of the present invention, the electrical circuit path is connected to or part of a capacitive switch. Preferably, the capacitive switch is also made from conductive ink/paint applied to the back surface of the film layer.

In a preferred embodiment of the present invention, the inventive trim piece comprises a flexible projection. This flexible projection is preferably part of the film layer and contains part of the conductive circuit. This projection is preferably not covered with the substrate and can be used to connect the inventive trim piece to the remaining car electronics

These and other features and advantages of various exemplary embodiments of systems and methods according to this invention are described in, or are apparent from, the following detailed descriptions of various exemplary embodiments of various devices, structures and/or methods according to this invention.

### BRIEF DESCRIPTION OF DRAWINGS

Various exemplary embodiments of the systems and methods according to this invention will be described in detail, with reference to the following figures, wherein:

FIG. 1 is a perspective view of the A-surface, or show surface, of a trim piece for a vehicle that uses an exemplary embodiment of capacitive switches according to the invention; and

FIG. 2 is a perspective view of the back surface of the trim piece of FIG. 1 showing the conductive paths of the capacitive switches.

### DETAILED DESCRIPTION OF EXEMPLARY EMBODIMENTS

During operation of an exemplary capacitive switch that may be useable with various exemplary embodiments of this invention, a signal is sent across a conductive pad and the capacitance of the pad is determined. For example, a square wave signal may be provided to the pad. During normal conditions, i.e., when the switch is not being touched, the pad has a low capacitance. As such, a circuit may be provided that quickly charges and drains, such as across a resistor, the pad in tune with the square wave signal. When a foreign object, such as a user's finger, touches or comes within close proximity to the switch, the foreign object increases the capacitance of the pad. The increased capacitance slows the rate at which the pad charges and drains and may be detected by appropriate devices and/or electrical circuits.

It should be appreciated that the above-outlined exemplary capacitive switch is just one type of numerous devices that may be referred to as capacitive switches and that may be useful with various exemplary embodiments of trim pieces. Other exemplary capacitive switches have multiple pads and/or conductive paths and may not need to be touched by a foreign object to be triggered. Such exemplary capacitive switches may also be referred to as field effect switches and/or near-field capacitive switches.

It should also be appreciated that some capacitive switches have one or more movable, flexible or otherwise displaceable parts. For example, a plunger may bring a first conductive material into close proximity with a second conductive material, creating a large capacitance between the two conductive materials that signals a reaction. Similarly, other capacitive switches may have flexing or otherwise displaceable surfaces, poppies or other functional regions as described in International Application PCT/US08/50287, which is incorporated herein by reference in its entirety. These flexing or otherwise displaceable surfaces, poppies or other functional regions provide tactile feedback to the user. It should be appreciated that any such capacitive switch or other appropriate switch, such as a field effect switch, may be used with various exemplary embodiments of trim pieces.

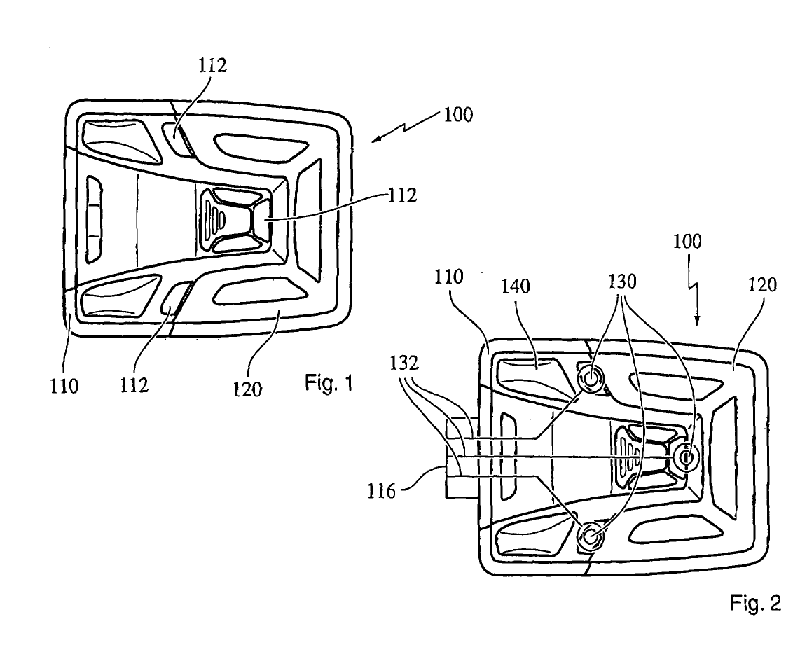

FIG. 1 shows the show surface of a trim piece 100 for a vehicle. The trim piece 100 includes a film layer 110 that provides a show surface for the trim piece 100 and a substrate 120 that carries and supports the film layer 110. As shown in FIG. 1, the film layer 110 of the trim piece 100 defines several button or switch regions 112. The switches associated with the button or switch regions 112 may control various aspects of the vehicle. For example, in various exemplary embodiments, two of the button or switch regions 112 are used to control interior lights of the vehicle, while a third button or switch region 112 is used to control a door of the vehicle. It should be appreciated that a button or switch region 112 may be usable to operate any desirable aspect of the vehicle or other connected electrical device. For example, a button or switch region 112 may be used to operate various functions of a speakerphone system. It should be appreciated that the button or switch regions 112 of the trim piece 100, may or may not include movable, flexible or otherwise displaceable parts.

FIG. 2 shows the back surface 114 of the film layer 110 of the trim piece 100 of FIG. 1. As shown in FIG. 2, three capacitive switches 130 are provided on the back surface 114 of the film layer 110 of the trim piece 100. A conductive circuit path 132 extends from each capacitive switch 130, and is used to electrically connect each capacitive switch 130 to the rest of the control circuitry or other electrical components of the vehicle. A projection 116 of the film layer 110 extends generally laterally from one side of the trim piece 100. As outlined below, the substrate 120 will not be molded behind the projection 116. Each of the conductive circuit paths 132 continues onto the projection 116 of the film layer 110.

In this exemplary embodiment, the trim piece 100 is made by first pre-forming the film layer 110 to a desired shape. The capacitive switches 130 and the conductive circuit paths 132 are then provided on the back surface 114 of the film layer 110. Subsequently, the film layer 110 is placed in a mold and the substrate 120 is molded to the back surface 114 of the film layer 110. During the molding process, at least the projection 116 of the film layer 110 is shut off from the mold cavity using any suitable known or later-developed structures and/or methods. As such, the projection 116 does not have a substrate molded to its back surface and remains flexible. In this exemplary embodiment, the projection 116 is similar to a flexible circuit board and may be usable to electrically connect the conductive circuit paths 132 to the appropriate wiring provided in the vehicle to which the trim piece 100 is attached.

It should also be appreciated that the conductive elements, such as the capacitive switches 130 and the conductive circuit paths 132, is made of any suitable, for example carbon based, conductive inks and/or paints. Likewise, the conductive elements, such as the capacitive switches 130 and the conductive circuit paths 132, may be provided on the back surface 114 of the film layer 110 using any suitable method such as, for example, silk screening, painting, metal deposition, injection molding and/or any other suitable known or later-developed method.

The inventive method of making a trim piece for a vehicle comprises providing a film layer having a front show surface and a back surface, providing a conductive electrical circuit onto the back surface of the film layer, and applying, preferably molding, a substrate to at least a first portion of the back surface of the film layer. Meanwhile, the substrate is not molded onto at least a second portion of the back surface of the film layer. The second portion of the back surface contains at least a portion of the conductive electrical circuit. This part can be used as a flexible projection, for example to connect the trim piece to the car-electronics.

According to a preferred embodiment of the present invention, a trim piece for a vehicle comprises a film layer having a front show surface and a back surface is provided. The film layer further has a first portion and a second portion. A conductive electrical circuit is provided onto the back surface of the film layer, such that at least a first portion of the conductive electrical circuit is provided onto the first portion of the film layer and at least a second portion of the conductive electrical circuit is provided onto the second portion of the film layer. A substrate is molded to the back surface of at least the first portion of the film layer such that the substrate is smaller than the back surface of the film layer.

The trim piece for a vehicle preferably comprises a capacitive switch. The capacitive switch includes a conductive layer provided on or over a film layer of the trim piece. By providing the conductive layer on or over the trim piece, the number of components necessary to assemble the trim piece can be reduced. Additionally, the conductive layer can be located closer to the A-surface or show surface of the vehicle, while reducing or eliminating the size of air gaps between the conductive layer and the show surface of the trim piece. This can improve the sensitivity and/or the reliability of the capacitive switch.

### LIST OF REFERENCE SIGNS

100 trim piece
110 film layer
112 switch region
114 back surface
116 projection
120 substrate
130 capacitive switch
132 circuit path, conductive ink

1. Process for the production of a interior trim piece, comprising the steps of:
providing a film layer
applying conductive ink/paint to the back surface of the film layer to provide an electrical circuit path and
attaching a substrate on the back surface of the film layer.

2. A process according to claim 1, characterized in, that the conductive ink/paint is printed, sprayed and/or screen-printed on the film layer.

3. A process according to claim 1, characterized that the substrate is molded behind the film layer.

4. A process according to claim 1, characterized that the film layer is preformed to a desired shape.

5. A process according to claim 1, characterized in, that the substrate covers only partially the back surface of the film layer.

6. Interior trim piece comprising a film layer with an electrical circuit path on its back surface, characterized in, that the electrical circuit path is made from conductive ink/paint.

7. An interior trim piece according to claim 6, characterized in, that it comprises at least partially a substrate at the back surface of the film layer.

8. An interior trim piece according to claim 6, characterized in, that the film layer is made from a flexible material.

9. An interior trim piece according to claim 1, characterized in, that the electrical circuit path is connected to a capacitive switch.

10. An interior trim piece according to claim 9, characterized in, that the capacitive switch is also made from conductive ink/paint applied to the back surface of the film layer.

11. An interior trim piece according to Claim 6, characterized in, that it comprises a flexible projection.

12. A process according to claim 4 wherein the film layer is preformed to a desired shape after the conductive ink/paint has been applied.
